(19) United States
(12) Patent Application Publication
(10) Pub. No.: US 2026/0304930 A1
(43) Pub. Date: Oct. 1, 2026

(54) MULTI-GATE DEVICES WITH REDUCED PARASITIC CAPACITANCE AND METHODS OF FORMING THE SAME

(71) Applicant: Taiwan Semiconductor Manufacturing Company, Ltd., Hsin-Chu (TW)

(72) Inventors: Hsu-Chia Huang, Hsinchu City (TW); Shih-Che Lin, Hsinchu (TW); Bau-Ming Wang, Kaohsiung City (TW); Te-Jui Yen, Hsinchu City (TW); Chia-Cheng Chen, Hsin-Chu City (TW)

(21) Appl. No.: 19/279,590

(22) Filed: Jul. 24, 2025

Related U.S. Application Data
(60) Provisional application No. 63/781,519, filed on Apr. 1, 2025.

(51) Int. Cl. H10D 84/83; H01L 21/02; H10D 30/00; H10D 30/01; H10D 62/10; H10D 62/13; H10D 64/23

(52) U.S. Cl. CPC H10D 84/832; H10D 30/0191; H10D 30/502; H10D 62/121; H10D 62/151; H10D 64/256; H10P 14/6309

(57) ABSTRACT

Semiconductor devices and methods of forming the same are provided. In an embodiment, an exemplary method includes receiving a precursor structure comprising an active region disposed over a substrate and extending lengthwise along a first direction, a source/drain feature disposed over the active region, a top portion of the source/drain feature is above a top surface of a channel region of the active region, and a gate structure comprising a gate dielectric layer over the active region and a gate electrode over the gate dielectric layer, the gate electrode comprising a titanium-containing material. The method also includes performing an etching process to partially remove the top portion of the source/drain feature, at least partially converting a remaining part of the top portion of the source/drain feature into a dielectric layer, and after the converting, forming a source/drain contact electrically coupled to the source/drain feature.

### PRIORITY DATA

The present application claims priority to U.S. Provisional Patent Application Ser. No. 63/781,519, filed Apr. 1, 2025, the entire disclosure of which is hereby incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices are introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. The channel region of a GAA transistor may be formed from nanowires, nanosheets, other nanostructures, and/or other suitable structures. Although existing multi-gate devices are generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming a semiconductor device, according to one or more aspects of the present disclosure.

FIG. 2 illustrates a fragmentary top view of an exemplary precursor structure to undergo various stages of operations in the method of FIG. 1 to form the semiconductor device, according to various aspects of the present disclosure.

FIGS. 3A, 4A, 5A, 6A, 7A, 8A, 9A, 10A, 11A, 12A, 13A, 14A and 15A (FIGS. 3A-15A) illustrate fragmentary cross-sectional views of the precursor structure taken along line A-A′ as shown in FIG. 2 during various fabrication stages in the method of FIG. 1, according to one or more aspects of the present disclosure.

FIGS. 3B, 4B, 5B, 6B, 7B, 8B, 9B, 10B, 11B, 12B, 13B, 14B and 15B (FIGS. 3B-15B) illustrate fragmentary cross-sectional views of the precursor structure taken along line B-B′ as shown in FIG. 2 during various fabrication stages in the method of FIG. 1, according to various aspects of the present disclosure.

FIG. 16 illustrates an enlarged portion of the precursor structure shown in FIG. 15B.

FIGS. 17 and 18 illustrate fragmentary cross-sectional views of alternative semiconductor devices, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

The present disclosure provides GAA transistors with reduced parasitic capacitance. In an exemplary embodiment, a method for forming a GAA transistor with reduced parasitic capacitance includes, after forming a source/drain contact opening, a treatment is performed to, for example, oxidize a portion of the source/drain feature extending along a gate spacer and over a topmost channel member (e.g., nanostructure). In various embodiments, the treatment may include thermal oxidization or plasma treatment. Due to the performing of the treatment, the portion of the source/drain feature is converted from a semiconductor material to a dielectric material. Thus, parasitic capacitance between the source/drain feature and an adjacent gate structure may be advantageously reduced.

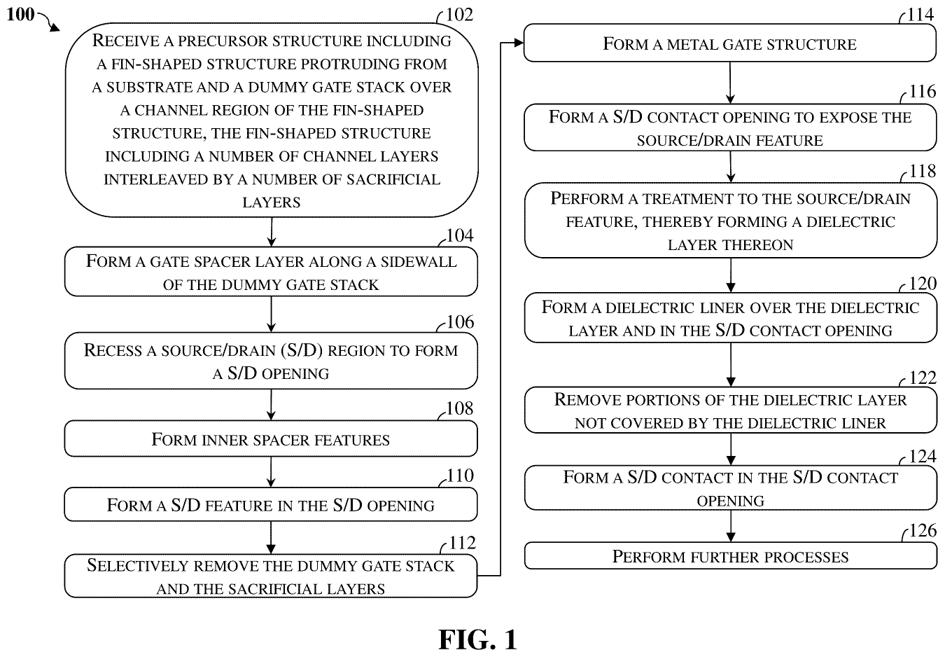

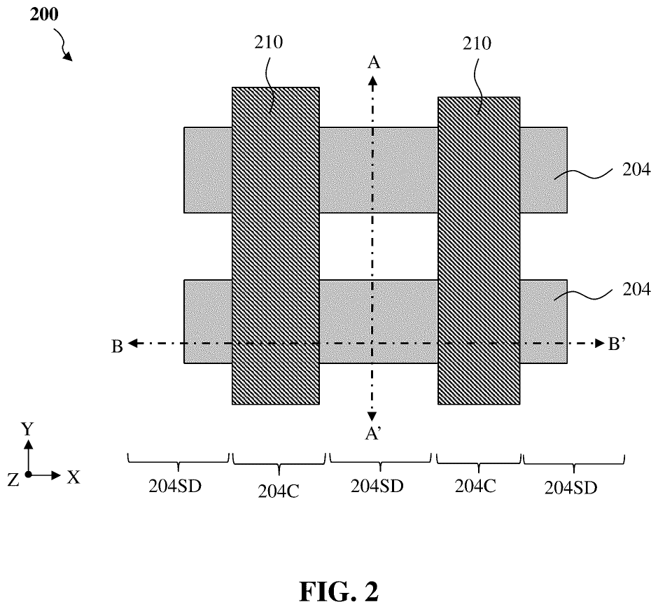

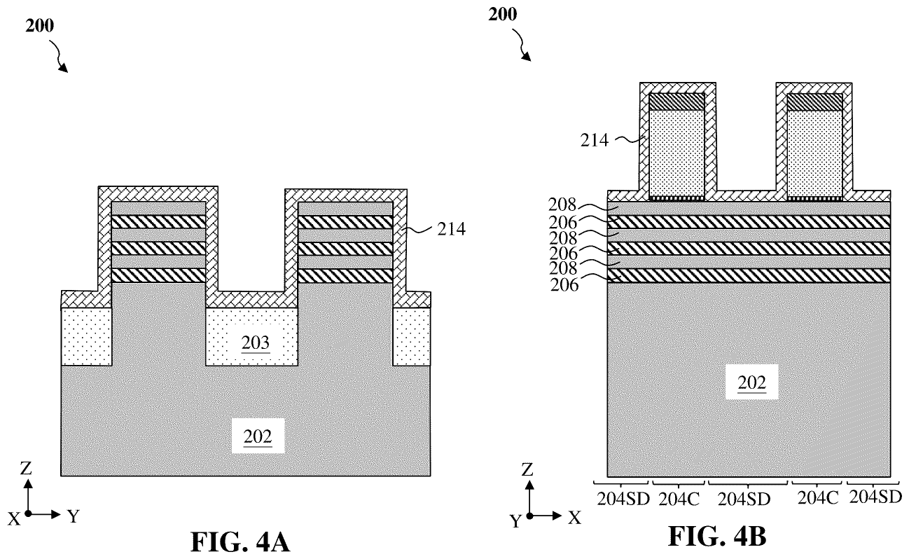

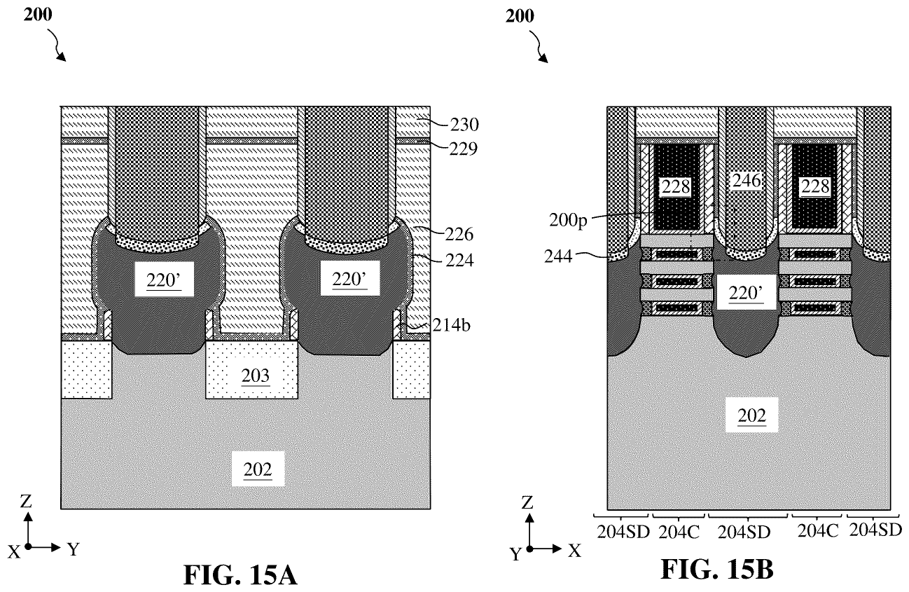

The various aspects of the present disclosure will now be described in more detail with reference to the figures. In that regard, FIG. 1 is a flowchart illustrating method 100 of forming a semiconductor device according to embodiments of the present disclosure. Method 100 is described below in conjunction with FIGS. 2, 3A-15A, 3B-15B, 16, 17, and 18, which are fragmentary top or cross-sectional views of a precursor structure 200 at different stages of fabrication according to embodiments of method 100. Method 100 is merely an example and is not intended to limit the present disclosure to what is explicitly illustrated therein. Additional steps may be provided before, during and after the method 100, and some steps described can be replaced, eliminated, or moved around for additional embodiments of the method. Not all steps are described herein in detail for reasons of simplicity. Because the precursor structure 200 will be fabricated into a semiconductor device upon conclusion of the fabrication processes, the precursor structure 200 may be referred to as the semiconductor device 200 as the context requires. For avoidance of doubts, the X, Y and Z directions in FIGS. 2, 3A-15A, 3B-15B, and 16-18 are perpendicular to one another and are used consistently throughout the present disclosure. Throughout the present disclosure, like reference numerals denote like features unless otherwise excepted.

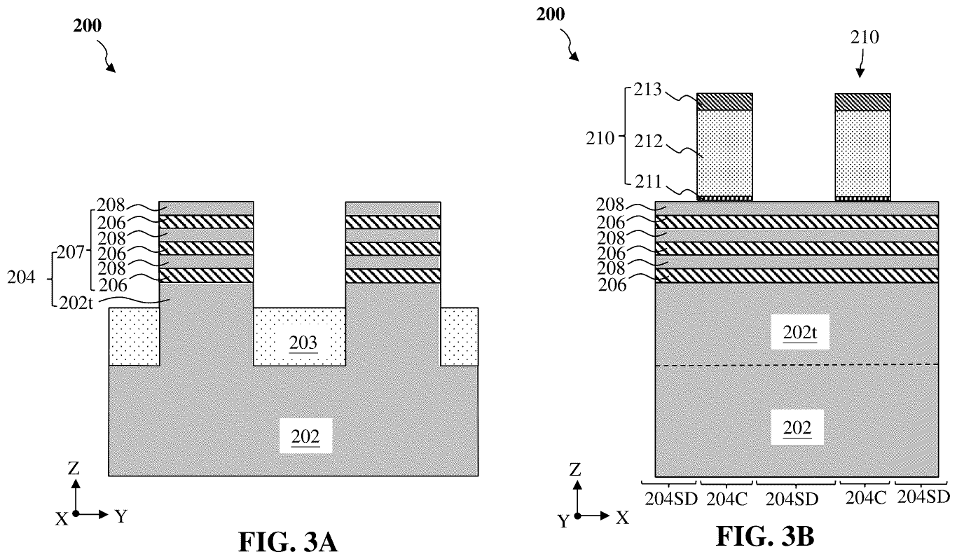

Referring to FIGS. 1, 2, and 3A-3B, method 100 includes a block 102 where a precursor structure 200 is received. FIG. 2 illustrates a fragmentary top view of the precursor structure 200. FIGS. 3A and 3B illustrate fragmentary cross-sectional views of the precursor structure 200 taken along line A-A′ and B-B′ as shown in FIG. 2, respectively, according to one or more aspects of the present disclosure. The precursor structure 200 includes a substrate 202. In an embodiment, the substrate 202 is a bulk silicon substrate (i.e., including bulk single-crystalline silicon). The substrate 202 may include other semiconductor materials in various embodiments, such as germanium, silicon carbide, gallium arsenide, gallium phosphide, indium phosphide, indium arsenide, indium antimonide, SiGe, GaAsP, AlInAs, AlGaAs, GaInAs, GaInP, GaInAsP, or combinations thereof. In some alternative embodiments, the substrate 202 may be a semiconductor-on-insulator substrate, such as a silicon-on-insulator substrate, a silicon germanium-on-insulator substrate, or a germanium-on-insulator substrate.

The precursor structure 200 includes a number of active regions (e.g., fin-shaped structures 204) protruding from the substrate 202. As shown in FIG. 2, each of the fin-shaped structures 204 extends lengthwise along the X direction. In an embodiment, a width of the fin-shaped structures 204 along the Y direction may be between about 4 nm and about 300 nm. The fin-shaped structure 204 is divided into channel regions 204C overlapped by dummy gate stacks 210 (to be described below) and source/drain (S/D) regions 204SD adjacent to the channel regions 204C. Source/drain (S/D) regions may refer to a source or a drain, individually or collectively dependent upon the context. In embodiments represented in FIGS. 3A-3B, the fin-shaped structure 204 is formed from a portion 202t of the substrate 202 and a vertical stack 207 of alternating first semiconductor layers and second semiconductor layers using a combination of lithography and etch steps. In the depicted embodiment, the vertical stack 207 includes a number of channel layers 208 interleaved by a number of sacrificial layers 206. The channel layer 208 may be formed of silicon (Si) and the sacrificial layer 206 may be formed of silicon germanium (SiGe). In some other embodiments, the channel layer 208 may include Ge, Sn, silicon germanium, silicon germanium tin, doped silicon (e.g., Si:P), III-V semiconductor materials, or other suitable materials. The channel layers 208 and the sacrificial layers 206 may be epitaxially deposited on the substrate 202 using molecular beam epitaxy (MBE), vapor-phase epitaxy (VPE), ultra-high vacuum chemical vapor deposition (UHV-CVD), and/or other suitable epitaxial growth processes. In the present embodiments, the fin-shaped structure 204 includes three pairs of alternating sacrificial layers 206 and channel layers 208. A thickness of the channel layer 208 may be between about 2 nm and about 20 nm. A thickness of the sacrificial layer 206 may be between about 5 nm and about 30 nm. In some embodiments, the fin-shaped structure 204 may include a total of one to twenty pairs of alternating sacrificial layers 206 and channel layers 208; of course, other configurations may also be applicable depending upon specific design requirements.

The precursor structure 200 also includes an isolation feature 203 formed around each fin-shaped structure 204 to isolate the fin-shaped structure 204 from an adjacent fin-shaped structure. The isolation feature 203 may also be referred to as a shallow trench isolation (STI) feature and may include silicon oxide, silicon oxynitride, fluorine-doped silicate glass (FSG), a low-k dielectric, combinations thereof, and/or other suitable materials.

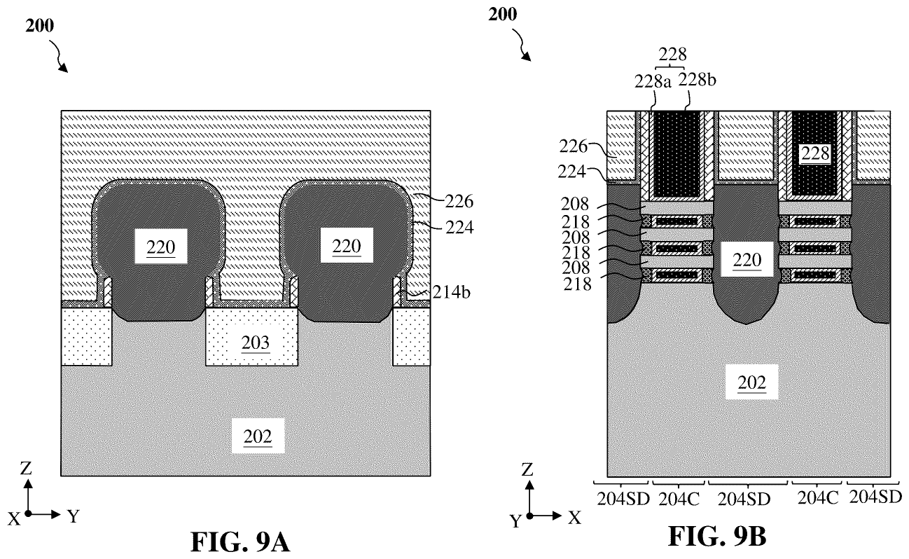

Still referring to FIGS. 2, 3A, and 3B, the precursor structure 200 also includes dummy gate stacks 210 disposed over channel regions 204C of the fin-shaped structure 204. The channel regions 204C and the dummy gate stacks 210 also define source/drain (S/D) regions 204SD that are not vertically overlapped by the dummy gate stack 210. Two dummy gate stacks 210 are shown in FIG. 2, but the precursor structure 200 may include more dummy gate stacks 210. In this embodiment, a gate replacement process (or gate-last process) is adopted where the dummy gate stacks 210 serve as placeholders for functional metal gate structures 228 (shown in FIG. 9B). Other processes and configuration are possible. The dummy gate stack 210 includes a dummy dielectric layer 211, a dummy gate electrode layer 212 over the dummy dielectric layer 211, and a gate-top hard mask layer 213 over the dummy gate electrode layer 212. The dummy dielectric layer 211 may include silicon oxide. The dummy gate electrode layer 212 may include polysilicon. The gate-top hard mask layer 213 may be a multi-layer structure that includes a silicon oxide layer and silicon nitride layer formed on the silicon oxide layer. Suitable deposition process, photolithography and etching process may be employed to form the dummy gate stacks 210.

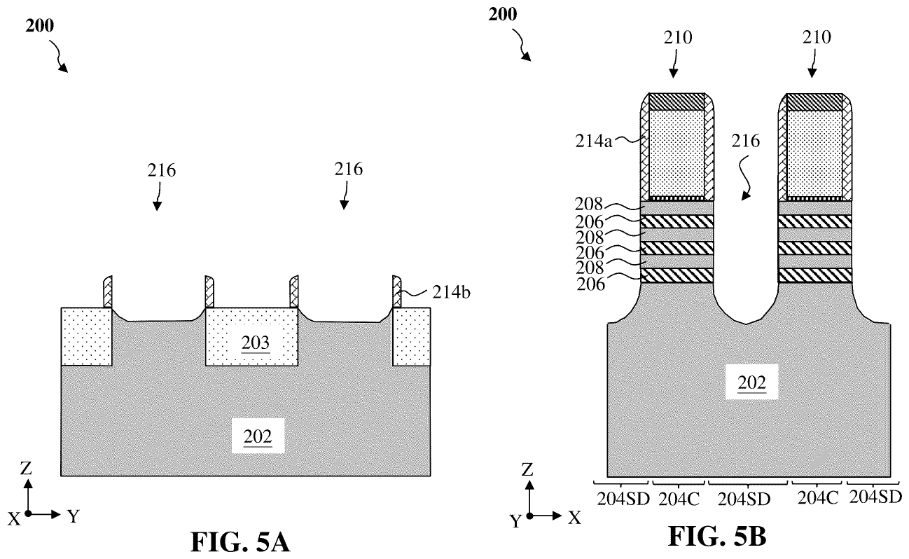

Referring to FIGS. 1, 4A-4B and 5A-5B, method 100 includes a block 104 where a gate spacer 214a is formed along a sidewall of the dummy gate stack 210. In some embodiments, the formation of the gate spacer 214a includes forming a gate spacer layer 214 over the precursor structure 200. The forming of the gate spacer layer 214 includes conformal deposition of one or more dielectric layers. In some embodiments, the gate spacer layer 214 may be deposited using chemical vapor deposition (CVD), sub-atmospheric chemical vapor deposition (SACVD), or atomic layer deposition (ALD) and may include silicon oxide, silicon nitride, silicon carbide, silicon oxynitride, silicon carbonitride, silicon oxycarbide, silicon oxycarbonitride, combinations thereof, or other suitable materials. With reference to FIGS. 5A-5B, the gate spacer layer 214 is then etched back to form gate spacers 214a extending along sidewall surface of the dummy gate stack 210. The etch back of the gate spacer layer 214 may also form fin sidewall spacers 214b extending along sidewall surfaces of the fin-shaped structures 204. That is, the gate spacers 214a and the fin sidewall spacers 214b are formed simultaneously. As shown in FIGS. 5A-5B, the gate spacer layer 214 is etched back to remove portions of the gate spacer layer 214 from, for example, top surfaces of the gate-top hard mask layers 213, top surfaces of the fin-shaped structures 204, and top surfaces of the isolation features 203 to form the gate spacers 214a (shown in FIG. 5B) and the fin sidewall spacers 214b (shown in FIG. 5A). In some embodiments, the etch back of the gate spacer layer 214 may include performing an anisotropic etching process. In the present embodiment, the fin sidewall spacers 214b are in direct contact with top surfaces of the isolation features 203 and cover portions of the sidewall surfaces of the fin-shaped structures 204. In the present embodiments, the fin sidewall spacers 214b are formed simultaneously along with the gate spacers 214a by etching the same gate spacer layer 214. In some embodiments, the precursor structure 200 may not include the fin sidewall spacers 214b.

Referring to FIGS. 1 and 5A-5B, method 100 includes a block 106 where source/drain regions 204SD of the fin-shaped structures 204 are recessed to form source/drain openings 216. In some embodiments, the source/drain regions 204SD are anisotropically etched by a dry etching or other suitable etching processes to form source/drain openings 216. An exemplary dry etching process may implement an oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In embodiments represented in FIGS. 5A and 5B, the source/drain openings 216 extend through the vertical stack 207 and partially extend into the substrate 202. As illustrated in FIG. 5B, sidewalls of the channel layers 208 and the sacrificial layers 206 are exposed in the source/drain openings 216.

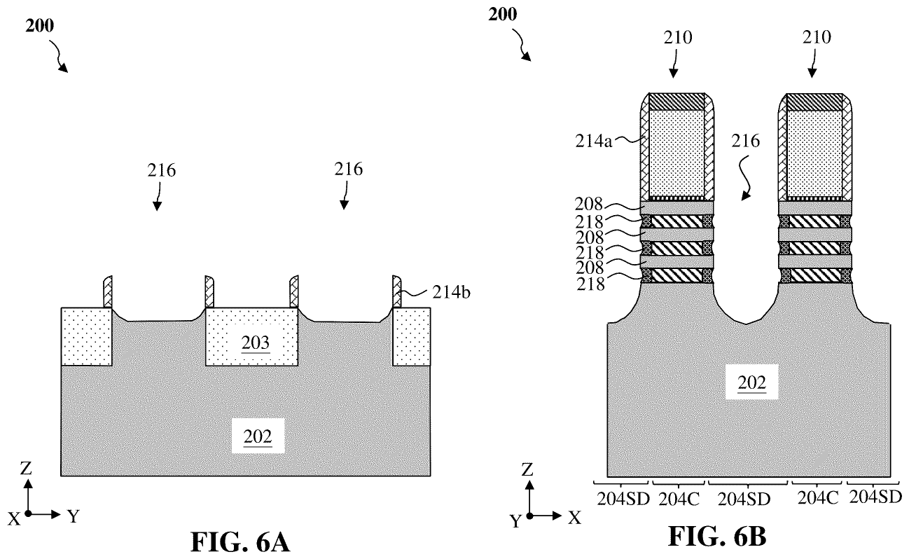

Referring to FIGS. 1 and 6A-6B, method 100 includes a block 108 where inner spacer features 218 are formed. After the formation of the source/drain openings 216, the sacrificial layers 206 are exposed in the source/drain openings 216 and then selectively and partially recessed to form inner spacer recesses, while the exposed channel layers 208 are substantially unetched. In embodiments where the channel layers 208 consist essentially of silicon (Si) and sacrificial layers 206 consist essentially of silicon germanium (SiGe), the selective and partial recess of the sacrificial layers 206 may include use of a selective isotropic etching process (e.g., a selective dry etching process or a selective wet etching process), and the extent at which the sacrificial layers 206 are recessed is controlled by duration of the etching process. A dielectric material layer may be then conformally deposited over the precursor structure 200, including in the inner spacer recesses, by ALD, CVD, or any other suitable deposition processes. The term “conformally” may be used herein for ease of description of a layer having substantially uniform thickness over various regions of the precursor structure 200. The dielectric material layer may be then etched back to form the inner spacer features 218. The dielectric layer may include silicon oxide, silicon nitride, silicon oxycarbide, silicon oxycarbonitride, silicon carbonitride, metal nitride, or a suitable dielectric material. Notably, the formation of the inner spacer features 218, including respective manufacturing steps described above, may be optional. That is, the formation of the inner spacer features 218 may be omitted, and the inner spacer features 218 may not exist in the final structure, in some embodiments.

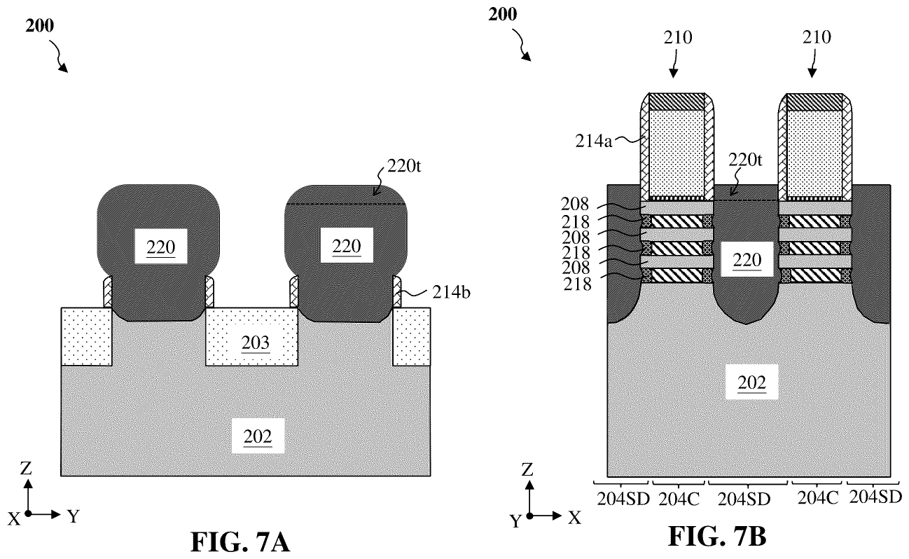

Referring to FIGS. 1 and 7A-7B, method 100 includes a block 110 where source/drain features 220 are formed in the source/drain openings 216. Source/drain feature(s) may refer to a source or a drain, individually or collectively dependent upon the context. An epitaxial process, such as VPE, UHV-CVD, MBE, and/or other suitable processes, is performed to form the source/drain feature 220 in the source/drain opening 216. The epitaxial growth process may use gaseous and/or liquid precursors (e.g., SiH₄, Si₂H₆, SiH₂Cl₂, GeH₄, Ge₂H₆, HCl, Cl₂), which interact with the composition of the substrate 202 as well as the channel layers 208. The epitaxial growth of the source/drain feature 220 may take place from both the exposed top surface of the substrate 202 and the exposed sidewalls of the channel layers 208. The epitaxial growth process may be stopped until the source/drain opening 216 is substantially filled. In various embodiments, after the performing of the epitaxial growth process, a top surface of the source/drain feature 220 is above a top surface of a topmost channel layer of the channel layers 208. That is, a top portion 220t (shown in FIG. 7B) of the source/drain feature 220 extends along a lower portion of a sidewall surface of the gate spacer. As illustrated by FIG. 7A, the source/drain feature 220 overhangs the isolation feature 203.

Depending on the conductivity type of the to-be-formed transistor, the source/drain features 220 may be n-type source/drain features or p-type source/drain features. Exemplary n-type source/drain features may include silicon, phosphorus-doped silicon, arsenic-doped silicon, antimony-doped silicon, or other suitable materials and may be in-situ doped during the epitaxial process by introducing an n-type dopant, such as phosphorus, arsenic, or antimony, or ex-situ doped using a junction implant process. Exemplary p-type source/drain features may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process.

In various embodiments, the source/drain feature 220 may include a second epitaxial semiconductor layer over a first epitaxial semiconductor layer. The concentration of dopants in the second epitaxial semiconductor layer is greater than the concentration of dopants in the first epitaxial semiconductor layer. In some embodiments, the source/drain feature 220 may also include an undoped epitaxial layer formed under the first epitaxial semiconductor layer. For example, the undoped epitaxial layer may be formed in a lower portion of the source/drain opening 216 that extended into the substrate 202.

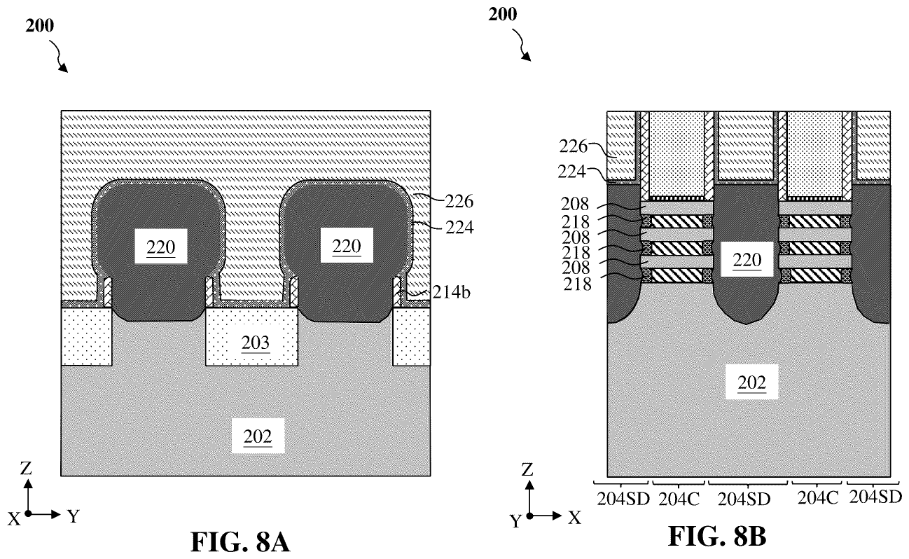

Referring to FIGS. 1, 8A-8B, and 9A-9B, method 100 includes a block 112 where the dummy gate stacks 210 and the sacrificial layers 206 are selectively removed. In embodiments represented in FIGS. 8A-8B, a contact etch stop layer (CESL) 224 and a first interlayer dielectric layer (ILD) layer 226 are deposited over the precursor structure 200. The CESL 224 may include silicon nitride, silicon oxynitride, and/or other materials known in the art and may be formed by ALD, plasma-enhanced chemical vapor deposition (PECVD) process, CVD, and/or other suitable methods and/or other suitable deposition or oxidation processes. The first ILD layer 226 is deposited over the CESL 224 by a PECVD process or other suitable deposition technique. The first ILD layer 226 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. A planarization process, such a chemical mechanical polishing (CMP) process may be performed to the precursor structure 200 to remove excess materials and expose top surfaces of the dummy gate electrode layers 212 in the dummy gate stacks 210.

With the exposure of the dummy gate electrode layers 212, block 112 proceeds to removal of the dummy gate stack 210. The removal of the dummy gate stack may include performing one or more etching process selective to the materials in the dummy gate stack 210 to form a number of gate trenches. For example, the removal of the dummy gate stack 210 may be performed using a selective wet etch, a selective dry etch, or a combination thereof. After the removal of the dummy gate stack 210, the sacrificial layers 206 are selectively removed to release the channel layers 208 as channel members (e.g., nanostructures) 208 in the channel regions 204C. The selective removal of the sacrificial layers 206 may be implemented by a selective dry etch, a selective wet etch, or other selective etching process. In some embodiments, the selective wet etching includes an APM etch (e.g., ammonia hydroxide-hydrogen peroxide-water mixture). The selective removal of the number of sacrificial layers 206 forms a number of gate openings.

Referring to FIGS. 1 and 9A-9B, method 100 includes a block 114 where a metal gate structure 228 is formed. After the selective removal of the dummy gate stack 210 and sacrificial layers 206, a metal gate structure 228 is formed in the gate openings and the gate trench. The metal gate structure 228 wraps around the channel members 208 and over the channel members 208. The metal gate structure 228 may include a gate dielectric layer 228a and a gate electrode layer 228b over the gate dielectric layer 228a. In some embodiments, the gate dielectric layer 228a includes an interfacial layer disposed on the channel members 208 and a high-k dielectric layer over the interfacial layer. Here, a high-k dielectric layer refers to a dielectric material having a dielectric constant greater than that of silicon dioxide, which is about 3.9. In some embodiments, the interfacial layer includes silicon oxide. The high-k dielectric layer is then deposited over the interfacial layer using ALD, CVD, and/or other suitable methods. The high-k dielectric layer may include hafnium oxide. Alternatively, the high-k dielectric layer may include other high-k dielectrics, such as titanium oxide, hafnium zirconium oxide, tantalum oxide, hafnium silicon oxide, zirconium silicon oxide, lanthanum oxide, aluminum oxide, yttrium oxide, SrTiO₃, BaTiO₃, BaZrO, hafnium lanthanum oxide, lanthanum silicon oxide, aluminum silicon oxide, hafnium tantalum oxide, hafnium titanium oxide, (Ba,Sr)TiO₃ (BST), silicon nitride, silicon oxynitride, combinations thereof, or other suitable material.

The gate electrode layer 228b is then deposited over the gate dielectric layer 228a using ALD, physical vapor deposition (PVD), CVD, e-beam evaporation, or other suitable methods. The gate electrode layer 228b may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 228b may include titanium nitride, titanium aluminum, titanium aluminum nitride, tantalum nitride, tantalum aluminum, tantalum aluminum nitride, tantalum aluminum carbide, tantalum carbonitride, aluminum, tungsten, nickel, titanium, ruthenium, cobalt, platinum, tantalum carbide, tantalum silicon nitride, copper, other refractory metals, or other suitable metal materials or a combination thereof. In an embodiment, the gate electrode layer 228b is a titanium-containing conductive layer. Further, where the semiconductor device 200 includes n-type transistors and p-type transistors, different gate electrode layers may be formed separately for n-type transistors and p-type transistors, which may include different work function metal layers (e.g., for providing different n-type and p-type work function metal layers). In some embodiments, after forming metal gate structure 228, the metal gate structure 228 may be recessed and a self-aligned cap layer may be formed on the metal gate structure 228.

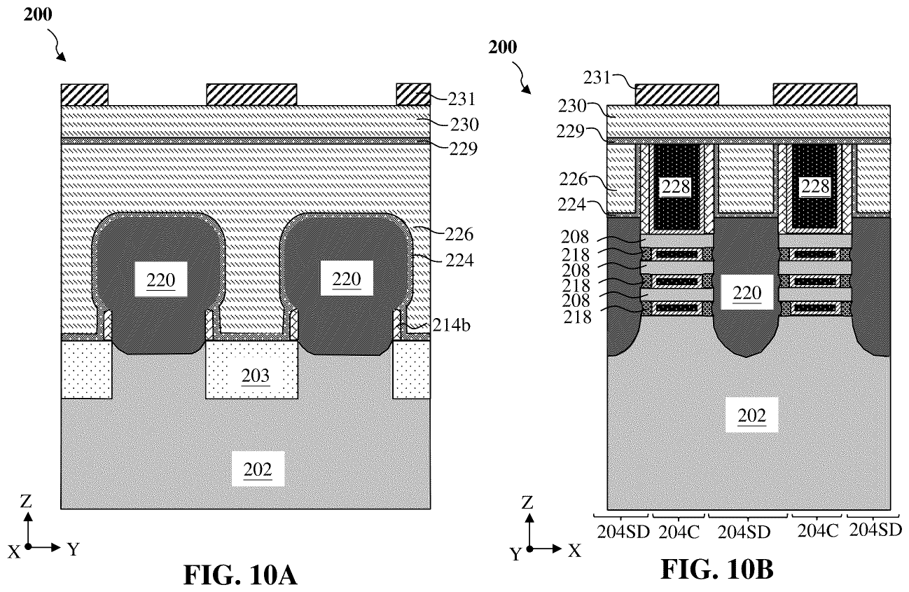

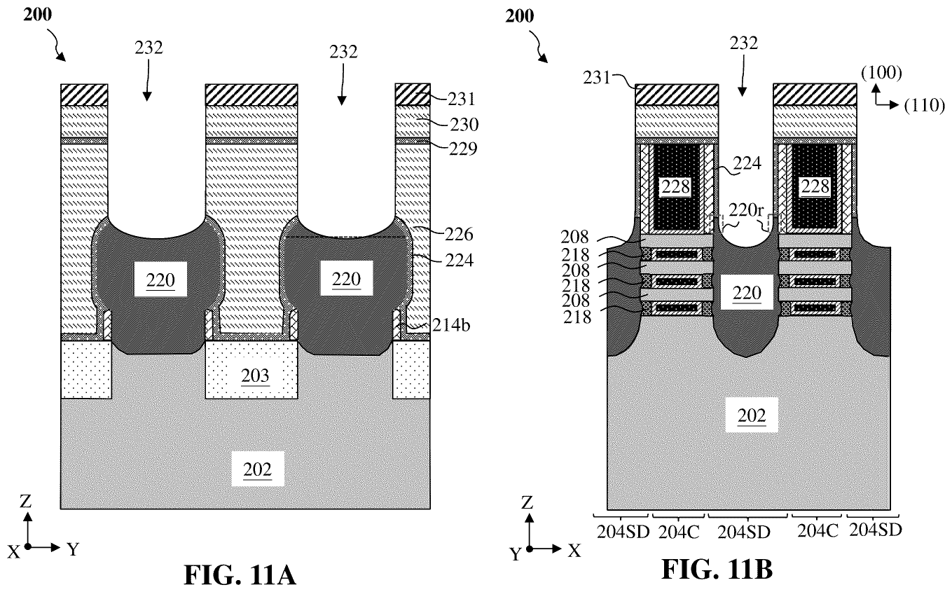

Referring to FIGS. 1, 10A-10B, and 11A-11B, method 100 includes a block 116 where a source/drain contact opening 232 is formed. After forming the metal gate structure 228, in an embodiment, an etch stop layer 229 is formed over the metal gate structure 228, the CESL 224 and the first ILD layer 226, and a second ILD layer 230 is formed on the etch stop layer 229. The formation and composition of the etch stop layer 229 may be similar to those of the CESL 224, and formation and composition of the second ILD layer 230 may be similar to those of the first ILD layer 226, and repeated description is omitted for reason of simplicity. As shown in FIGS. 10A-10B and 11A-11B, a patterned mask 231 may be formed on the second ILD layer 230. While using the patterned mask 231 as an etch mask, an etching process is conducted to remove portions of the second ILD layer 230, the etch stop layer 229, the first ILD layer 226, and the CESL 224 not covered by the patterned mask 231 to form source/drain contact openings 232. In various embodiments, after the performing of the etching process, at least a part of the top portion 220t of the source/drain feature 220 remains on the sidewall of the gate spacer 214a, as represented by FIG. 11B. This part of the source/drain feature 220 may be referred to as residue 220r. The residue 220r may be formed due to various reasons. For example, in some embodiments, an etch rate for etching the source/drain feature 222 may be related to the orientation of the source/drain feature. In an embodiment, the etching process etches the source/drain feature 222 from (100) orientation at a first etch rate that is greater than a second etch rate for etching the source/drain feature 222 from (111) orientation and (110) orientation; in some other embodiments, to keep the integrity of the gate spacer 214a, the portion of the CESL 224 extending along the sidewall of the gate spacer 214a is not fully removed. The residue 220r, if left untreated, may lead to an increased parasitic capacitance between the metal gate structure 228 and the source/drain feature 220. The present disclosure provides a method of reducing or even eliminating the residue 220r without affecting characteristics of the channel members 208, the CESL 224, and the gate spacer 214a.

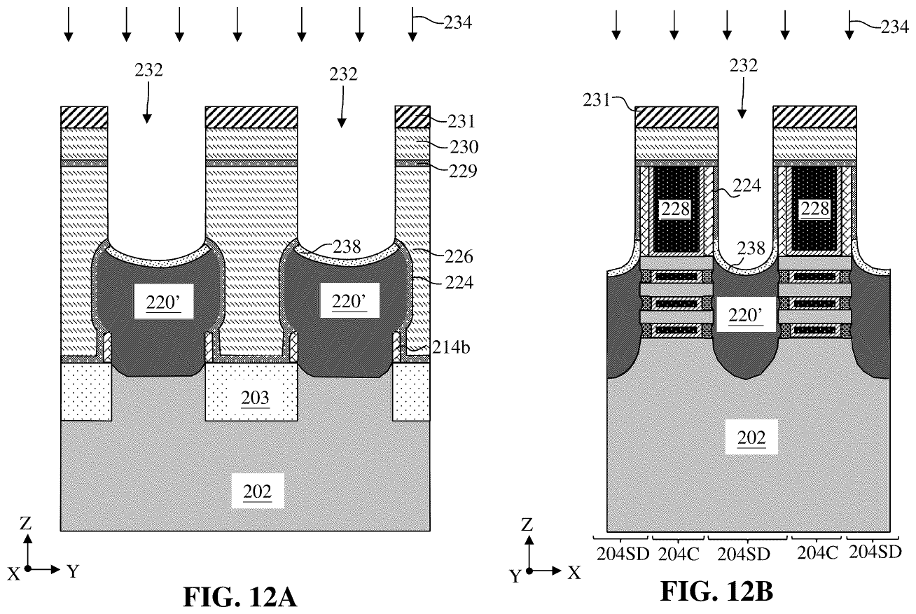

Referring to FIGS. 1, 12A, and 12B, method 100 includes a block 118 where a treatment 234 is performed to the source/drain feature 220. After forming the source/drain contact opening 232, the source/drain feature 220 is exposed. The treatment 234 is then performed to the exposed source/drain feature 220. Upon completion of the treatment 234, an upper portion of the source/drain feature 220, including the residue 220r, is converted from a semiconductor material to a dielectric layer 238. In an embodiment, the treatment 234 includes a thermal oxidization process. The thermal oxidization process may be performed in an oxygen-containing environment and at a processing temperature ranging from about 25° C. to about 300° C. If the processing temperature is lower than 25° C., the dielectric layer 238 may not be substantially formed; and if the processing temperature is higher than 300° C., more dopants in the source/drain feature 220 may diffuse into its neighboring features (e.g., the substrate 202), leading to a decreased dopant concentration in the source/drain feature and an increased parasitic resistance. In some other embodiments, the treatment 234 includes a plasma treatment. The plasma treatment may be an isotropic such that the residue 220r disposed under the CESL 224 would undergo a chemical reaction. The plasma treatment may include use of an oxygen (O₂) plasma, a nitrogen (N₂) plasma, or a combination of the nitrogen (N₂) plasma and the oxygen (O₂) plasma.

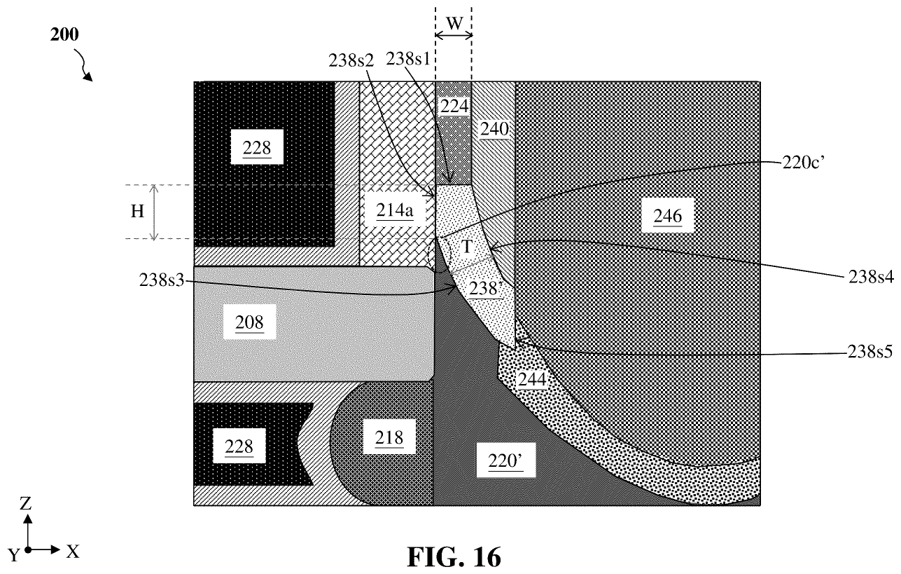

The source/drain feature 220 after being treated by the treatment 234 is referred to as the source/drain feature 220'. The dielectric layer 238 is formed on the source/drain feature 220′ and does not extend along surfaces of dielectric features (e.g., the CESL 224, the first ILD layer 226, and the patterned mask 231). More specifically, an entirety of a top surface of the source/drain feature 220′ is covered by the dielectric layer 238. The duration of the performing of the treatment 234 is controlled such that the residue 220r is partially or even fully oxidized or nitridated, while the topmost channel member 208 adjacent to the residue 220r remains unchanged. In an embodiment, a thickness T (shown in FIG. 16) of the dielectric layer 238 may be less than about 10 nm and greater than about 1 nm. If the thickness T is too small, then the residue 220r may not be substantially reduced to reduce a parasitic capacitance, and if the thickness T is too large, then a sidewall of the topmost channel member 208 may be covered by the dielectric layer 238, decreasing the performance of the transistor. In another embodiment, the thickness T is about 1 nm to about 3 nm.

The composition of the dielectric layer 238 depends on parameters (e.g., plasma source, temperature) of the treatment 234 and the composition of the source/drain feature 220. In an embodiment, the source/drain feature 220 includes silicon, and the resulted dielectric layer 238 may include silicon oxide, silicon nitride, and/or silicon oxynitride (SiON). In another embodiment, the source/drain feature 220 includes silicon germanium, and the resulted dielectric layer 238 may include germanium-containing oxide (e.g., GeO, SiGeO), silicon oxide, silicon nitride, and/or silicon oxynitride (SiON). In an embodiment, an oxygen concentration of the dielectric layer 238 is greater than an oxygen concentration of the CESL 224. For example, the CESL 224 includes silicon nitride, and the dielectric layer 238 includes silicon oxide or silicon oxynitride.

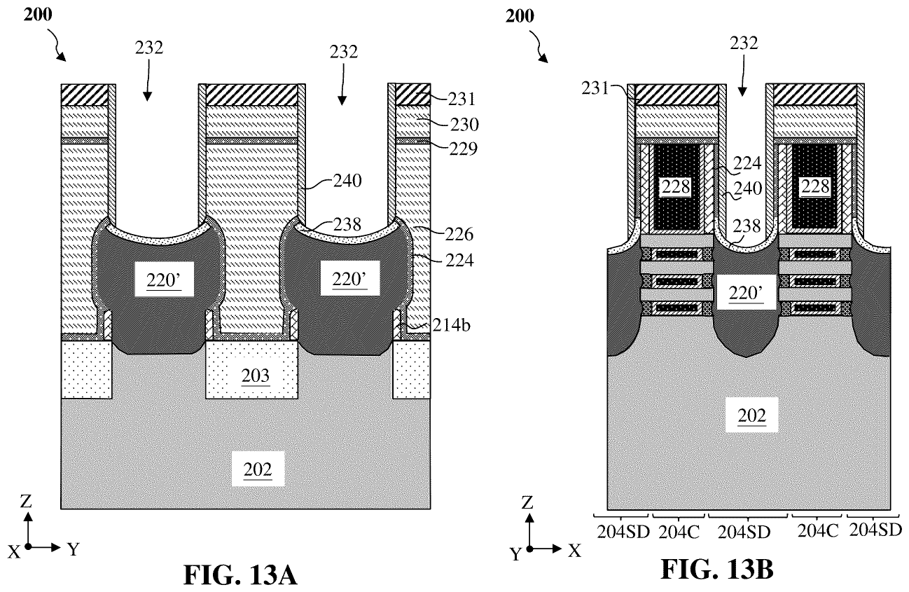

Referring to FIGS. 1 and 13A-13B, method 100 includes a block 120 where a dielectric liner 240 is formed to extend along a sidewall surface of the source/drain contact opening 232. After the formation of the dielectric layer 238, a dielectric barrier layer is conformally deposited over the substrate 202, including in the source/drain contact opening 232. A composition of the dielectric barrier layer is selected such that the dielectric barrier layer is more etch resistant than the dielectric layer 238 with respect to some etchants. In an embodiment, a dielectric constant of the dielectric barrier layer is greater than a dielectric constant of the dielectric layer 238. The dielectric barrier layer is then etched back to only cover sidewalls of the source/drain contact opening 232 and expose the top surface of the source/drain feature 220′. The etched back dielectric barrier layer forms the dielectric liner 240 in the source/drain contact opening 232. In some embodiments, the dielectric liner 240 may include silicon nitride or other suitable materials. A nitrogen concentration of the dielectric liner 240 may be higher than a nitrogen concentration of the dielectric layer 238. An oxygen concentration of the dielectric liner 240 may be lower than an oxygen concentration of the dielectric layer 238. In an embodiment, the dielectric liner 240 includes silicon nitride, and the dielectric layer 238 includes silicon oxide or silicon oxynitride. In an embodiment, the CESL 224 and the dielectric liner 240 have the same composition. As illustrated by FIGS. 13A-13B, the dielectric liner 240 covers a portion of the dielectric layer 238.

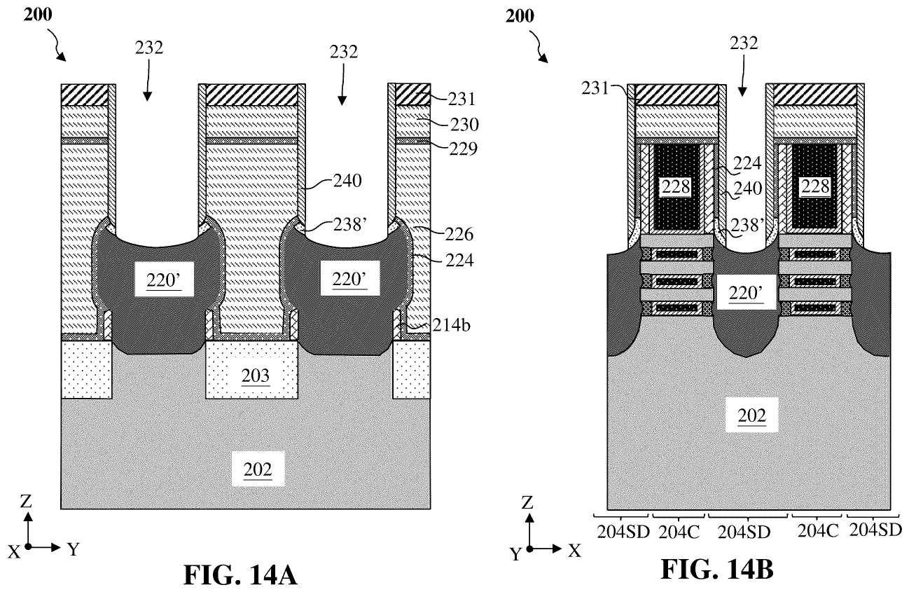

Referring to FIGS. 1 and 14A-14B, method 100 includes a block 122 where the dielectric layer 238 not covered by the CESL 224 and the dielectric liner 240 is selectively removed. After forming the dielectric liner 240, an etching process is performed to selectively remove the portion of the dielectric layer 238 not covered by the dielectric liner and the CESL 224, thereby exposing a top surface of the source/drain feature 220′. The dielectric layer 238 after the performing of the etching process in block 122 is referred to as a dielectric layer 238′.

Referring to FIGS. 1, 15A-15B, and 16, method 100 includes a block 124 where a source/drain contact is formed in the source/drain contact opening 232. In an embodiment, a silicide layer 244 is formed on the source/drain feature 220′. To form the silicide layer 244, a metal layer is deposited (by ALD, CVD and/or other deposition processes) over the precursor structure 200, including on the exposed top surface of the source/drain feature 220′, and an anneal process is then performed to bring about silicidation reaction between the metal layer and the source/drain feature 220′. Portions of the metal layer that does not form the silicide layer 244 may be removed. Suitable metal layer may include titanium, tantalum, nickel, cobalt, or tungsten. In embodiments where the metal layer includes nickel and the source/drain feature 220′ includes silicon germanium, the silicide layer 244 includes nickel silicide, nickel germanide, and nickel germanosilicide. In some other embodiments, the silicide layer 244 may include titanium silicide, tantalum silicide, cobalt silicide, or tungsten silicide.

A source/drain contact 246 is then formed in the source/drain contact opening 232 and over the silicide layer 244. After the formation of the silicide layer 244, a conductive layer may be deposited over the precursor structure 200 to fill the source/drain contact opening 232 by PVD, CVD, or other suitable processes. The conductive layer may include aluminum, rhodium, ruthenium, copper, iridium, or tungsten. A planarization process, such as a CMP process, may be followed to remove excessive portions of the conductive layer, thereby forming the source/drain contact 246. The source/drain contact 246 is electrically coupled to the source/drain feature 220′ by way of the silicide layer 244.

FIG. 16 depicts an enlarged portion 200p of the precursor structure 200 including the source/drain contact 236. As depicted in FIG. 16, the dielectric layer 238′ has a top surface 238s1 contacting a bottom surface of the CESL 224. The top surface 238s1 spans a width W. In an embodiment, the width W is about 1 nm to about 10 nm. In another embodiment, the width W is about 1 nm to about 3 nm. The dielectric layer 238′ has a sidewall surface 238s2 contacting a sidewall surface of the gate spacer 214a. In an embodiment, the sidewall surface 238s2 is a substantially vertical surface. The sidewall surface 238s2 spans a height H. In an embodiment, the height H is between about 1 nm and about 10 nm. In another embodiment, the height H is about 2 nm to about 4 nm. The dielectric layer 238′ has a bottom surface 238s3 contacting a top surface of the source/drain feature 220′. The bottom surface 238s3 may be a curved surface that curves outward towards the topmost channel member 208. The dielectric layer 238′ has a sidewall surface 238s4 extending from the top surface 238s1 and contacting a bottom surface of the dielectric liner 240. The sidewall surface 238s4 may be a curved surface that curves inward towards the topmost channel member 208. The dielectric layer 238′ also has a sidewall surface 238s5 connecting the bottom surface 238s3 and the sidewall surface 238s4 and contacting the silicide layer 244 and/or the source/drain contact 246. In this embodiment, the sidewall surface 238s5 is vertically aligned with a sidewall surface of the dielectric liner 240 contacting the source/drain contact 246. In this depicted embodiment, the source/drain feature 220′ has a top corner portion 220c′ extending along the gate spacer 214a and over the topmost channel member 208. However, due to the formation of the dielectric layer 238′, a volume of the top corner portion 220c′ is much less than a volume of the residue 220r, leading to a reduced parasitic capacitance. For example, in the cross-sectional view represented by FIG. 16, an area of the top corner portion 220 c′ is less than 1 nm².

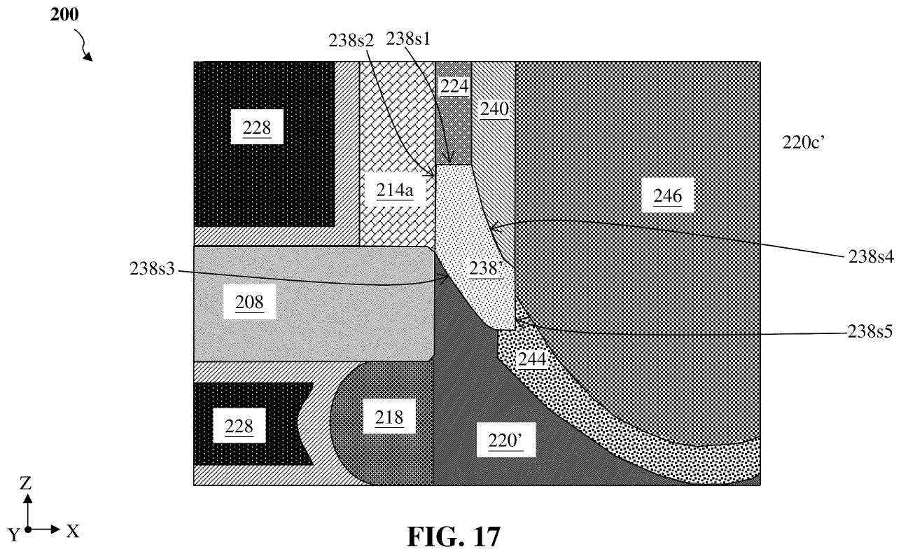

In another alternative embodiment represented by FIG. 17, an entirety of the source/drain feature 220′ is disposed under the gate spacer 214a. That is, the residue 220r is fully converted, and the source/drain feature 220′ is free of the top corner portion 220c′. In this embodiment, the sidewall surface of the gate spacer 214a is covered by the CESL 224 and the dielectric layer 238′. It is noted that, the topmost channel member 208 is spaced apart from the dielectric layer 238′ by the source/drain feature 220′.

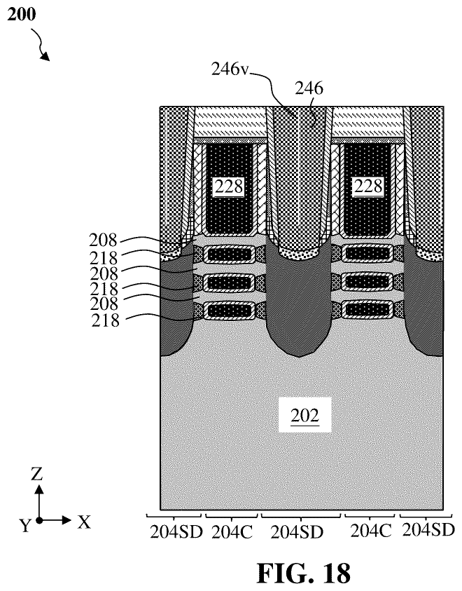

In another alternative embodiment represented by FIG. 18, at different stages of fabrication according to embodiments of method 100, profiles of various features of the precursor structure 200 may be changed. For example, in some embodiments, a profile of the channel member 208 may be similar to a dog-bone shape. This may be caused due to the slightly etch of the channel layers 208 during the removal of the sacrificial layers 206 and during the formation of the inner spacer features 218. In some embodiments, the source/drain contact 246 may include a seam or void 246v enclosed by a conductive material layer. This may be formed during the deposition of the conductive material layer. In the above embodiments, the source/drain contact openings 232 and thus features (e.g., the dielectric liner 240 and the source/drain contact 246) formed therein may include substantially vertical sidewalls. In some other embodiments represented by FIG. 18, the source/drain contact openings 232 may include has an inverted tapered profile and thus have tilted sidewalls. And the dielectric liner 240 and the source/drain contact 246 formed therein may also include tilted sidewalls. In such cases, the sidewall surface 238s5 of the dielectric layer 238′ and the sidewall of the dielectric liner 240 may be portions of a linear surface.

Referring to FIG. 1, method 100 includes a block 126 where further processes are performed. Such further processes may include forming a multi-layer interconnect (MLI) structure (not depicted) over or under the precursor structure 200. The MLI may include various interconnect features, such as vias and conductive lines, disposed in dielectric layers, such as etch-stop layers and ILD layers. In some embodiments, the vias are vertical interconnect features configured to interconnect device-level contacts, such as gate contacts (not depicted) formed over the metal gate structure 228.

Although not intended to be limiting, one or more embodiments of the present disclosure provide many benefits to a semiconductor device and the formation thereof. The present disclosure provides methods and structures that can provide a multi-gate device (e.g., such as a GAA transistor) having a reduced parasitic capacitance. More specifically, the parasitic capacitance between the gate structure of the transistor and source/drain features of the transistor and thus associated resistive-capacitive (RC) delay may be advantageously reduced.

The present disclosure provides for many different embodiments. Semiconductor devices and methods of fabrication thereof are disclosed herein. In one exemplary aspect, the present disclosure is directed to a method. The method includes receiving a precursor structure comprising an active region comprising a channel region and a source/drain region, an isolation feature disposed alongside the active region, a gate structure disposed over the channel region, a gate spacer disposed along a sidewall of the gate structure, a source/drain feature disposed over the source/drain region, a contact etch stop layer (CESL) disposed over the source/drain feature, and an interlayer dielectric (ILD) layer disposed over the CESL, wherein a portion of the CESL extends along a sidewall of the gate spacer such that the gate spacer is between the gate structure and the CESL. The method also includes forming a trench extending through the CESL and ILD layer to expose the source/drain feature, after the forming of the trench, performing a treatment to the exposed source/drain feature, thereby converting a portion of the exposed source/drain feature to a dielectric layer, the dielectric layer comprising an end portion disposed adjacent to the channel region and a middle portion near the end portion of the dielectric layer, removing the middle portion of the dielectric layer, and after the removing of the middle portion of the dielectric layer, forming a source/drain contact in the trench.

In some embodiments, the performing of the treatment may include performing a thermal oxidation process or performing a plasma treatment using an oxygen-containing source or a nitrogen-containing source. In some embodiments, the source/drain feature and the dielectric layer may include a same semiconductor element. In some embodiments, the dielectric layer may include silicon oxide, silicon nitride, or silicon oxynitride. In some embodiments, the method may also include, after the performing of the treatment, forming a dielectric liner extending along sidewalls of the trench, the end portion of the dielectric layer is covered by the CESL and the dielectric liner. In some embodiments, the end portion of the dielectric layer extends along a lower portion of a sidewall of the gate spacer, and the CESL extends along an upper portion of the sidewall of the gate spacer. In some embodiments, a dielectric constant of the dielectric layer is less than a dielectric constant of the CESL and a dielectric constant of the dielectric liner. In some embodiments, the channel region may include a plurality of nanostructures, and the end portion of the dielectric layer is disposed over a topmost nanostructure of the plurality of nanostructures. In some embodiments, the precursor structure may also include inner spacers disposed under the gate spacer and between the gate structure and the source/drain feature.

In another exemplary aspect, the present disclosure is directed to a method. The method includes a forming an active region over a substrate and extending lengthwise along a first direction, forming an isolation feature over the substrate and alongside the active region, forming a source/drain feature over the active region, wherein a portion of the source/drain feature overhangs the isolation feature along a second direction different from the first direction, and wherein a top portion of the source/drain feature is above a top surface of a channel region of the active region, forming a gate structure comprising a gate dielectric layer over the active region and a gate electrode over the gate dielectric layer, wherein the gate electrode comprises a titanium-containing material, converting a portion of the source/drain feature into a dielectric layer, and after the converting, forming a source/drain contact electrically coupled to the source/drain feature.

In some embodiments, the method may also include forming a contact etch stop layer (CESL) over the source/drain feature and adjacent to the gate structure, and forming an interlayer dielectric (ILD) layer on the CESL. In some embodiments, the method may also include forming a patterned mask over the CESL and ILD layer, the patterned mask comprising an opening over the source/drain feature, and performing an etching process to form a trench extending through the CESL and ILD layer and extending into the source/drain feature. In some embodiments, the performing of the etching process removes a part of the source/drain feature, and the converting is performed after the performing of the etching process. In some embodiments, the method may also include, after the converting, forming a dielectric liner extending along sidewalls of the trench and on the dielectric layer. In some embodiments, the converting may include performing a thermal oxidization process or a plasma process to oxidize the portion of the source/drain feature. In some embodiments, the dielectric layer is disposed laterally between the gate structure and the source/drain contact and disposed under the CESL.

In yet another exemplary aspect, the present disclosure is directed to a semiconductor device. The semiconductor device includes an active region comprising a channel region and a source/drain region adjacent to the channel region, a gate structure over the channel region, a gate spacer disposed along a sidewall of the gate structure, a source/drain feature over the source/drain region, a contact etch stop layer (CESL) over the source/drain feature, an interlayer dielectric (ILD) layer over the CESL, a source/drain contact extending through the ILD layer and the CESL, and a dielectric layer disposed vertically between the source/drain feature and the CESL, the source/drain contact is spaced apart from the gate structure by the CESL, the dielectric layer, and the gate spacer.

In some embodiments, the dielectric layer extends along a lower portion of a sidewall surface of the gate spacer, and the CESL extends along an upper portion of the sidewall surface of the gate spacer. In some embodiments, a dielectric constant of the dielectric layer is less than a dielectric constant of the CESL. In some embodiments, the semiconductor device may also include a dielectric liner disposed between the CESL and the source/drain contact and on the dielectric layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a precursor structure comprising:
an active region comprising a channel region and a source/drain region,
an isolation feature disposed alongside the active region,
a gate structure disposed over the channel region,
a gate spacer disposed along a sidewall of the gate structure,
a source/drain feature disposed over the source/drain region,
a contact etch stop layer (CESL) disposed over the source/drain feature, and
an interlayer dielectric (ILD) layer disposed over the CESL, wherein a portion of the CESL extends along a sidewall of the gate spacer such that the gate spacer is between the gate structure and the CESL;
forming a trench extending through the CESL and ILD layer to expose the source/drain feature;
after the forming of the trench, performing a treatment to the exposed source/drain feature, thereby converting a portion of the exposed source/drain feature to a dielectric layer, the dielectric layer comprising an end portion disposed adjacent to the channel region and a middle portion near the end portion of the dielectric layer;
removing the middle portion of the dielectric layer; and
after the removing of the middle portion of the dielectric layer, forming a source/drain contact in the trench.

2. The method of claim 1, wherein the performing of the treatment comprises performing a thermal oxidation process or performing a plasma treatment using an oxygen-containing source or a nitrogen-containing source.

3. The method of claim 1, wherein the source/drain feature and the dielectric layer comprise a same semiconductor element.

4. The method of claim 1, wherein the dielectric layer comprises silicon oxide, silicon nitride, or silicon oxynitride.

5. The method of claim 1, further comprising:
after the performing of the treatment, forming a dielectric liner extending along sidewalls of the trench, wherein the end portion of the dielectric layer is covered by the CESL and the dielectric liner.

6. The method of claim 5, wherein the end portion of the dielectric layer extends along a lower portion of a sidewall of the gate spacer, and the CESL extends along an upper portion of the sidewall of the gate spacer.

7. The method of claim 5, wherein a dielectric constant of the dielectric layer is less than a dielectric constant of the CESL and a dielectric constant of the dielectric liner.

8. The method of claim 1, wherein the channel region comprises a plurality of nanostructures, and the end portion of the dielectric layer is disposed over a topmost nanostructure of the plurality of nanostructures.

9. The method of claim 1, wherein the precursor structure further comprises inner spacers disposed under the gate spacer and between the gate structure and the source/drain feature.

10. A method, comprising:
forming an active region over a substrate and extending lengthwise along a first direction;
forming an isolation feature over the substrate and alongside the active region;
forming a source/drain feature over the active region, wherein a portion of the source/drain feature overhangs the isolation feature along a second direction different from the first direction, and wherein a top portion of the source/drain feature is above a top surface of a channel region of the active region;
forming a gate structure comprising a gate dielectric layer over the active region and a gate electrode over the gate dielectric layer, wherein the gate electrode comprises a titanium-containing material;
converting a portion of the source/drain feature into a dielectric layer; and
after the converting, forming a source/drain contact electrically coupled to the source/drain feature.

11. The method of claim 10, further comprising:
forming a contact etch stop layer (CESL) over the source/drain feature and adjacent to the gate structure, and
forming an interlayer dielectric (ILD) layer on the CESL.

12. The method of claim 11, further comprising:
forming a patterned mask over the CESL and ILD layer, the patterned mask comprising an opening over the source/drain feature; and
performing an etching process to form a trench extending through the CESL and ILD layer and extending into the source/drain feature.

13. The method of claim 12, wherein the performing of the etching process removes a part of the source/drain feature, and the converting is performed after the performing of the etching process.

14. The method of claim 12, further comprising:
after the converting, forming a dielectric liner extending along sidewalls of the trench and on the dielectric layer.

15. The method of claim 14, wherein the converting comprises performing a thermal oxidization process or a plasma process to oxidize the portion of the source/drain feature.

16. The method of claim 14, wherein the dielectric layer is disposed laterally between the gate structure and the source/drain contact and disposed under the CESL.

17. A semiconductor device, comprising:
an active region comprising a channel region and a source/drain region adjacent to the channel region;
a gate structure over the channel region;
a gate spacer disposed along a sidewall of the gate structure;
a source/drain feature over the source/drain region;
a contact etch stop layer (CESL) over the source/drain feature;
an interlayer dielectric (ILD) layer over the CESL;
a source/drain contact extending through the ILD layer and the CESL; and
a dielectric layer disposed vertically between the source/drain feature and the CESL,
wherein the source/drain contact is spaced apart from the gate structure by the CESL, the dielectric layer, and the gate spacer.

18. The semiconductor device of claim 17, wherein the dielectric layer extends along a lower portion of a sidewall surface of the gate spacer, and the CESL extends along an upper portion of the sidewall surface of the gate spacer.

19. The semiconductor device of claim 17, wherein a dielectric constant of the dielectric layer is less than a dielectric constant of the CESL.

20. The semiconductor device of claim 17, further comprising:
a dielectric liner disposed between the CESL and the source/drain contact and on the dielectric layer.
